(19) United States
(12) Patent Application Publication
(10) Pub. No.: US 2019/0310788 A1
(43) Pub. Date: Oct. 10, 2019

(54) SIMILARITY-BASED DATA DEDUPLICATION ON SOLID-STATE STORAGE DEVICES WITH EMBEDDED NONVOLATILE MEMORY

(71) Applicant: ScaleFlux, Inc., San Jose, CA (US)

(72) Inventors: Tong Zhang, Albany, NY (US); Yang Liu, Milpitas, CA (US); Fei Sun, Irvine, CA (US); Hao Zhong, Los Gatos, CA (US)

(21) Appl. No.: 16/376,008

(22) Filed: Apr. 5, 2019

Related U.S. Application Data
(60) Provisional application No. 62/654,253, filed on Apr. 6, 2018.

(51) Int. Cl. G06F 3/06; G06F 16/215; G06F 12/0802; H03M 7/30

(52) U.S. Cl. CPC G06F 3/0641; G06F 16/215; G06F 3/0608; G06F 2212/205; G06F 12/0802; H03M 7/3091; G06F 2212/1044; G06F 3/068

(57) ABSTRACT

A storage device and method for performing device level similarity-based data deduplication. A solid-state storage device is provided that includes: a set of flash memory; a nonvolatile memory (NVM) cache; and a controller that performs similarity-based data deduplication in response to write requests from a host, wherein the controller includes: a cache management module that temporarily stores a new data sector in NVM cache when a write request is received; a similarity detection module that determines if a similar data sector exists in flash memory; a data chunk management module that, in response to determining the similar data sector exists, generates a new data chunk that includes a metadata block, a base sector and at least one delta, wherein the new data chunk is stored in a newly allocated physical block address (PBA) in flash memory.

### TECHNICAL FIELD

The present invention relates to the field of solid-state data storage, and particularly to improving the storage space utilization of solid-state data storage devices.

### BACKGROUND

Aiming to eliminate the data redundancy and hence reduce data storage footprint and/or data transfer volume, data deduplication has become an indispensable feature in almost all the storage archive/backup systems and many front-end computing/storage systems. The basic principle of data deduplication can be described as follows: First, files are split into multiple chunks, where all the chunks may have the same or different size (typically at least a few kB and larger) depending upon whether content awareness is incorporated into the chunking process. Given each data chunk, data deduplication aims to discover and accordingly exploit the redundancy between a given chunk and the other chunks that have been stored or transferred in the system.

This is realized in either locality-based or similarity-based manner, where the former only focuses on exactly identical chunks and the latter considers both identical and highly similar chunks. In the context of locality-based data deduplication, for each individual chunk, a locality-oriented signature (or fingerprint) with a reasonably small size (e.g., 20 bytes or 32 bytes) is calculated using certain hash function (e.g., SHA-1 or SHA-256). The signature is used to determine whether two chunks are identical (i.e., if the signatures of two same-sized chunks are identical, then the two chunks are considered to be identical). In the context of similarity-based data deduplication, more complicated hashing schemes are used to calculate similarity-oriented signatures for each chunk. The signatures are used to determine whether two chunks are identical or highly similar. Once multiple identical data chunks are identified, the system only physically stores or transfers a single copy through appropriate data structure management. For similarity-based data deduplication, once multiple highly similar data chunks are identified, the system only physically stores or transfers a single copy and the inter-chunk deltas (i.e., differences) through appropriate data structure management.

Compared with locality-based deduplication, similarity-based data deduplication can achieve higher data reduction efficiency. However, practical realization of similarity-based data deduplication faces two fundamental challenges: (1) Since the system must keep track the location of the base data chunk and inter-chunk deltas, the data storage management tends to be very complicated; and (2) The system may need to read data from several different locations to reconstruct one data chunk, which leads to longer data read latency.

### SUMMARY

This disclosure presents techniques to address challenges associated with similarity-based data deduplication in order to enable practical and efficient implementation of similarity-based data deduplication for solid-state data storage devices. Accordingly, embodiments of the present disclosure are directed to systems and methods for improving the storage space utilization of solid-state data storage devices.

A first aspect provides a solid-state storage device, comprising: a set of flash memory; a nonvolatile memory (NVM) cache; and a controller that performs similarity-based data deduplication in response to write requests from a host, wherein the controller includes: a cache management module that temporarily stores a new data sector in NVM cache when a write request is received; a similarity detection module that determines if a similar data sector exists in flash memory; a data chunk management module that, in response to determining the similar data sector exists, generates a new data chunk that includes a metadata block, a base sector and at least one delta, wherein the new data chunk is stored in a newly allocated physical block address (PBA) in flash memory.

A second aspect provides a solid-state storage device, comprising: a set of flash memory; a nonvolatile memory (NVM) cache; and a controller that performs similarity-based data deduplication, wherein the controller includes logic to perform the following when requested to write a new sector of data: initially writing the new sector into NVM cache; determining if the new sector has a similar sector in the set of flash memory; in response to determining that no similar sector exists, allocating a new physical block address (PBA) and storing the new sector to flash memory; in response to determining that the similar sector exists, determining if the similar sector is part of a data chunk that includes deltas; in response to determining that the similar sector is not part of an existing data chunk that includes deltas, creating a new data chunk that includes a base sector and a delta, and storing the new data chunk in flash memory; in response to determining that the similar sector is part of the existing data chunk that includes deltas, determining whether a base sector of the existing data chunk still maps to a physical block address (PBA) of the existing data chunk; and in response to determining that the base sector of the existing data chunk still maps to the physical block address, obtaining a delta for the new sector, appending the delta to the existing data chunk, and storing an updated data chunk into flash memory.

A third aspect provides a method for performing similarity-based data deduplication within a storage device having flash memory and a nonvolatile memory (NVM) cache, comprising: temporarily storing a new sector in NVM cache on the data storage device after a write request is received; determining if a similar sector exists in flash memory; in response to determining the similar sector exists, generating a new data chunk that includes a metadata block, a base sector and at least one delta; and storing the new data chunk in a newly allocated physical block address (PBA) in flash memory.

### BRIEF DESCRIPTION OF THE DRAWINGS

The numerous advantages of the present invention may be better understood by those skilled in the art by reference to the accompanying figures in which:

FIG. 1 illustrates an example of similarity-based data deduplication among four similar data sectors.

FIG. 2 illustrates that similarity-based data deduplication only occurs among data sectors being stored in the same PBA in accordance with embodiments.

FIG. 3 illustrates the storage device hardware architecture in accordance with embodiments.

FIG. 4 illustrates the top-level operational flow diagram when serving a write request in accordance with embodiments.

FIG. 5 illustrates the overall operational flow diagram of processing each data sector in NVM cache for similarity-based data deduplication in accordance with embodiments.

FIG. 6 illustrates the operational flow diagram when a storage device serves a read request in accordance with embodiments.

### DETAILED DESCRIPTION

Reference will now be made in detail to the presently preferred embodiments of the invention, examples of which are illustrated in the accompanying drawings.

Modern solid-state data storage devices, e.g., solid-state drives (SSDs), are built with NAND flash memory chips. In addition to continuous progress of the underlying NAND flash memory fabrication technology, system-level data reduction (i.e., compression and deduplication) can further reduce the effective bit cost of solid-state data storage devices. This disclosure presents techniques to enable practical and efficient implementation of similarity-based data deduplication.

In particular, embodiments described herein provide in-storage similarity-based data deduplication with complete transparency to the users/applications. To facilitate the implementation of in-storage similarity-based data deduplication, solid-state data storage devices are disclosed that contain a small capacity nonvolatile memory (NVM) cache. The NVM cache can be implemented, e.g., using capacitor-powered SRAM or DRAM, or various new memory technologies such as 3DXP, phase-change memory, and STT-RAM.

As pointed out above, practical realization of similarity-based data deduplication faces two fundamental challenges: (1) Since the system must keep track the location of the base data chunk and inter-chunk deltas, the data storage management tends to be very complicated; and (2) The system may need to read data (i.e., base sector and deltas) from several different locations to reconstruct one data chunk, which leads to longer data read latency.

As understood in the art, solid-state data storage devices expose their storage space in an array of logical block addresses (LBAs), and the host always uses LBAs to access the data storage device. Each data block associated with each LBA is called a data sector, and the size of each data sector is typically 4 kB. Internally, solid-state data storage devices assign one unique physical block address (PBA) to each NAND flash memory storage segment that can physically store one data sector. Hence, solid-state data storage devices internally maintain an LBA-PBA mapping table that is indexed by LBAs and contains all the information about the mapping between LBAs and PBAs. Given a read request with the LBA Lᵢ, a solid-state data storage device looks up its LBA-PBA mapping table to find the corresponding PBA based upon which the storage device fetch the data from NAND flash memory. To ensure the storage consistency, each PBA also stores its associated LBA, i.e., reverse PBA-LBA mapping information is embedded into each PBA. Hence, in case of LBA-PBA mapping table corruption, storage devices can scan all the PBAs to reconstruct the LBA-PBA mapping table. When serving a read request, storage devices may even further check whether the requested LBA matches the LBA embedded in the PBA. In case of LBA mismatch, storage devices may notify the host about the LBA mismatch.

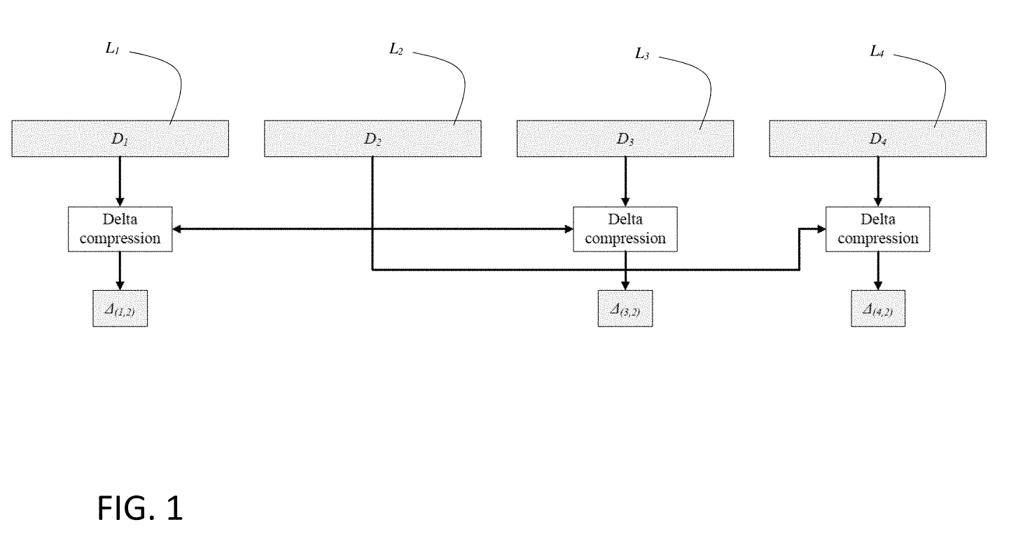

The purpose of similarity-based data deduplication is to eliminate the redundancy among multiple data sectors with similar data content. FIG. 1 illustrates an example of similarity-based data deduplication among four similar data sectors with the LBAs of L₁, L₂, L₃, and L₄. Let D₁, D₂, D₃, and D₄ denote the data content at these four LBAs. Assume we use the content D₂ as the base data sector for the other three data sectors, similarity-based data deduplication carries out delta compression to obtain a compact representation (i.e., a delta) of the difference between the base sector a similar sector: (1) the delta between D₁ and D₂, denoted as Δ_{(1,2)}, (2) the delta between D₃ and D₂, denoted as Δ_{(3,2)}, and (3) the delta between D₄ and D₂, denoted as Δ_{(4,2)}. After applying similarity-based data deduplication, the storage device only needs to store the base data sector D₂ and three deltas Δ_{(1,2)}, Δ_{(3,2)}, and Δ_{(4,2)}. The size (e.g., tens of bytes) of the three deltas is much smaller than the size of one data sector (e.g., 4 kB).

In conventional practice, since the four data sectors are written to the storage device at different times, the storage of the base data sector (i.e., D₂) and deltas (i.e., Δ_{(1,2)}, Δ_{(3,2)}, and Δ_{(4,2)}) most likely will be stored in different PBAs. As a result, the storage device must keep track of the correlation of these LBAs and PBAs, leading to very complicated data management. Moreover, to read a deduplicated data sector (e.g., L₁), the storage device must potentially read data from multiple PBAs, leading to a long data read latency.

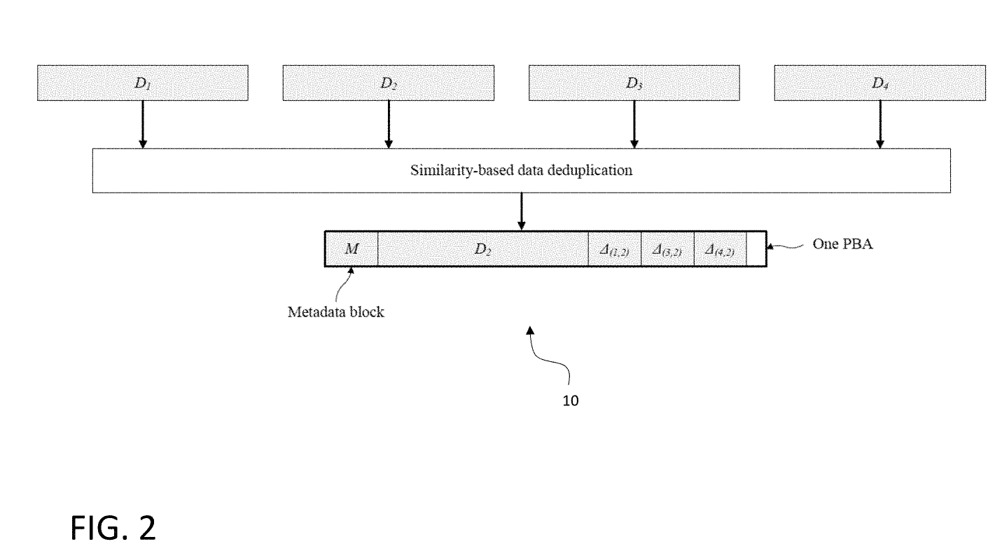

To address the challenges pointed out above, the present approach leverages a NVM cache to concatenate the base data sector and all its related deltas into a single data chunk, which is stored in a single PBA as shown e.g., in FIG. 2. For the purpose of this example, assume similarity-based data deduplication is carried out among four similar data sectors with the LBAs of L₁, L₂, L₃, and L₄. Let D₁, D₂, D₃, and D₄ denote the content of these four LBAs. Assume the content D₂ is used as the base sector for all the other three data sectors. After applying similarity-based data deduplication, the storage device stores the base data sector D₂ and three deltas Δ_{(1,2)}, Δ_{(3,2)}, and Δ_{(4,2)} together as a data chunk 10 in a single PBA. Accordingly, lossless data compression is applied to the base sector D₂, and a new data chunk 10 is formed by concatenating the compressed base sector D₂and the three deltas Δ_{(1,2)}, Δ_{(3,,2)}, and Δ_{(4,2)} together, as illustrated in FIG. 2.

To keep track of the data, a metadata block M is included with (e.g., appended to the front of) the data chunk 10, which includes the following information: (1) the size of the three deltas Δ_{(1,2)}, Δ_{(3,2)}, and Δ_{(4,2)}; and (2) the LBAs of the four data sectors within the data chunk 10, i.e., L₂, L₁, L₃, and L₄. As illustrated in FIG. 2, data chunk 10, including the metadata block M, is stored in one PBA in flash memory. In this way, similarity-based data deduplication results are only stored among data sectors in the same PBA, thus providing an enhanced deduplication storage arrangement.

In order to implement the enhanced deduplication storage arrangement, various technical issues must be addressed. For instance, because device-level (or “in-storage”) similarity-based data deduplication is completely transparent to the host, the host has no control over deduplication storage strategies. Further, since similarity-based data deduplication requires a relatively long latency, reading and writing operations can potentially overlap with deduplication operations. For instance, data in a PBA being processed by a deduplication strategy may no longer map to and a given LBA.

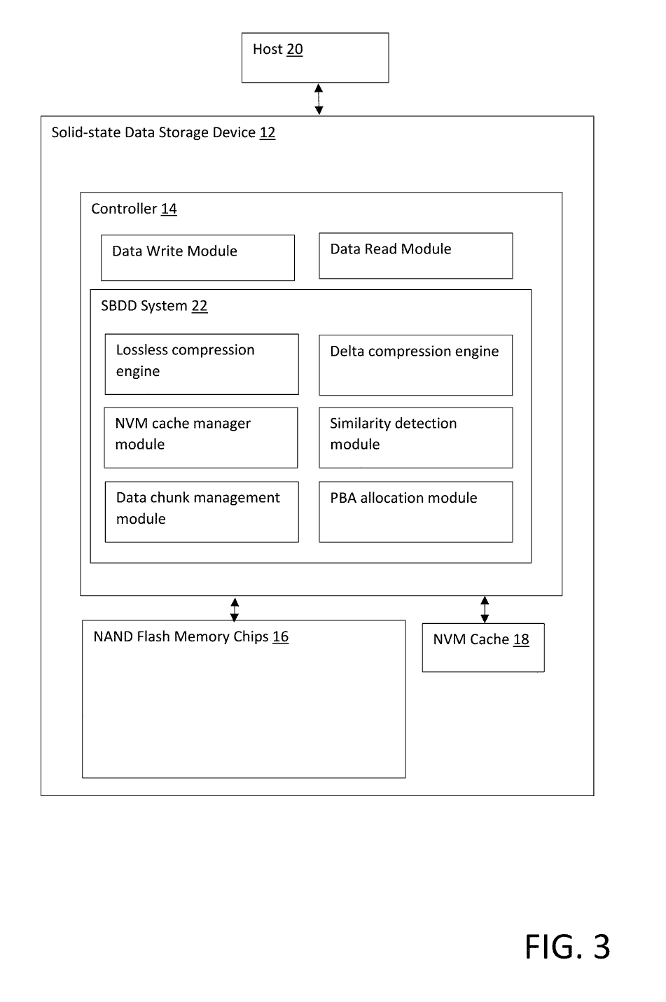

FIG. 3 depicts an illustrative solid-state data storage device (“storage device”) 12 configured to implement the enhanced deduplication storage arrangement. Storage device 12 generally includes a controller 14 having a data write module and a data read module, and NAND flash memory chips 16, which store and retrieve data to and from the host 20. Also included is a similarity-based data deduplication (SSDD) system 22 that leverages a small nonvolatile memory (NVM) cache 18 to facilitate the enhanced deduplication storage (as, e.g., shown in FIG. 2).

SSDD system 22, includes: a lossless compression engine that is utilized to compress and decompress base data sectors; a delta compression engine that is utilized to calculate deltas; an NVM cache manager module that manages data flow into and cleanup from NVM cache 18; a similarity detection module that determines if a new data sector temporarily written in NVM cache 18 has a similar data sector in flash memory 16; a data chunk management module that creates and accesses data chunks 10 (FIG. 2); and a PBA allocation module that stores and retrieves data chunks 10. Other controller components not shown for brevity purposes are understood to further facilitate the present embodiments.

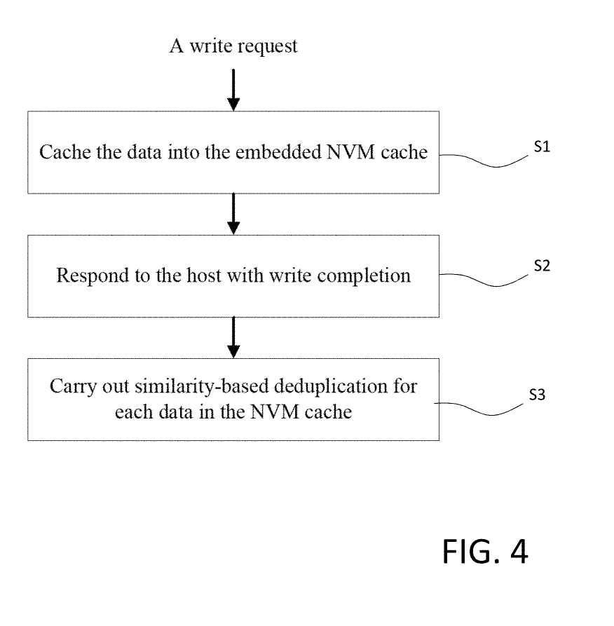

FIG. 4 illustrates a high-level operational flow diagram of the managed PBA implementation of similarity-based data deduplication when serving a write request. Upon each incoming write request, storage device 12 always first caches the incoming write request into the embedded NVM cache 18 at S1, after which the storage device 12 immediately sends a write completion acknowledgement to the host 20 at S2. At S3, the storage device 12 examines each data sector in the NVM cache 18 to determine whether the data sector can participate in similarity-based data deduplication with other data sectors already stored in NAND flash memory.

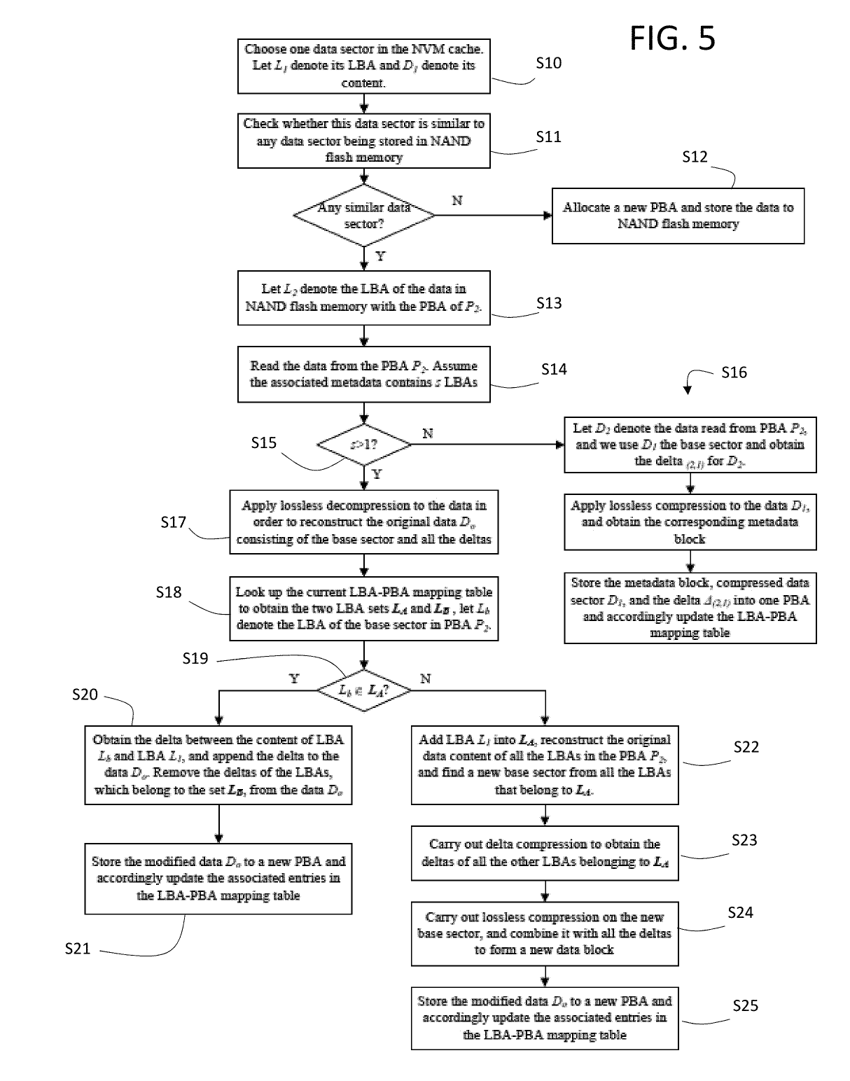

FIG. 5 provide an illustrative operational flow diagram of processing each data sector in NVM cache for similarity-based data deduplication. At S10, a first data sector being cached in NVM is chosen for which L₁ denotes its LBA and D₁ denote its content. At S11, a check is made whether this data sector is similar to any data sector being stored in NAND flash memory 16. If no, then the controller 14 directly stores this data sector to NAND flash memory 16 without any further processing at S12. Assume we store this data sector to the PBA P₁, we will accordingly update the LBA-PBA mapping table. Otherwise, if this data sector is similar to one existing data sector in NAND flash memory 16, then at S13 let L₂ denote the LBA of the similar data sector and which is stored in NAND flash memory 16 with the PBA of P₂. At S14, the data is read from the PBA P₂, and its metadata is checked to identify the number s of associated LBAs. At S15, a check is made whether the metadata includes only a single LBA (s=1) or multiple LBAs (s>1).

If s=1, this indicates that the PBA P₂ contains only one data sector with the LBA L₁ and there are no additional deltas associated with the stored LBA, i.e., no previous findings of similarity for the LBA L₁. In this case, logic proceeds along S16 in which D₂ denotes the data read from PBA P₂, and D₁ is used as the base sector and a delta Δ_{(2,1)} is obtained for D₂. Lossless compression is then applied to the data D₁, and the corresponding updated metadata block is obtained. Finally, the metadata block, compressed data sector D₁, and the delta Δ_{(2,1)} are stored into one PBA and the LBA-PBA mapping table is updated.

If at S15 the metadata from the PBA P₂ contains s>1 LBAs, this indicates that the storage device previously applied similarity-based data deduplication among these s LBAs. In this case, lossless decompression must be applied to the data at S17 in order to reconstruct the original data (denoted as D₀) consisting of the base sector and all the deltas. Next, at S18, the current LBA-PBA mapping table is checked to determine which of these s LBAs still map to the PBA P₂. In this example, the set L_{A} contains the LBAs that still map to PBA P₂ and the set L_{B} contains the remaining LBAs that no longer map to PBA P₂. In this approach, let L_{b} denote the LBA of the base sector in PBA P₂. Then at S19:

If L_{b} ϵ L_{A} (i.e., L_{b} belongs to the set L_{A}), then at S20 the delta between the contents of LBA L_{b} and LBA L₁ is obtained, and the delta is appended to the data D₀. Additionally, from the data D₀, the deltas are removed for the LBAs that belong to the set L_{B}. At S21, a new available PBA of NAND flash memory is allocated, the modified data D₀ is stored to this new PBA and the associated entries in the LBA-PBA mapping table are updated.

If L_{b} ϵ L_{B} (i.e., L_{b} does not belong to L_{A} but belongs to the set L_{B}), then at S22 the LBA L₁ is added into L_{A}, the original data content of all the LBAs in the PBA P₂ is reconstructed, and a new base sector from all the LBAs is found that belong to L_{A}. Using this new base sector, delta compression is carried out at S23 to obtain the deltas of all the other LBAs belonging to L_{A}. Next, at S24, lossless compression is carried out on the new base sector, and the base sector is combined with all the deltas to form a new data block. Finally, at S25, a new available PBA of NAND flash memory is allocated, the modified data D₀ is stored to this new PBA, and the associated entries in the LBA-PBA mapping table are accordingly updated.

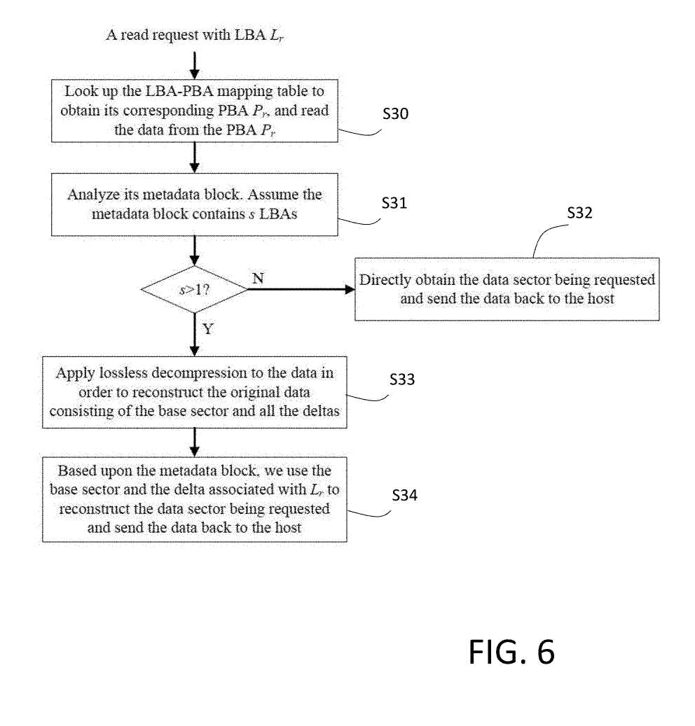

FIG. 6 illustrates the operational flow diagram when storage device 12 serves a read request. Given a read request with the LBA Lᵣ, a look up of the LBA-PBA mapping table occurs at S30 to obtain its corresponding PBA Pᵣ. Then, the data from the PBA Pᵣ is read, and its metadata block is analyzed at S31. Assume the metadata block contains s LBAs (s≥1), i.e., the storage device successfully applied similarity-based data deduplication among these s LBAs. If s=1 (i.e., the PBA P₂ contains only one data sector with the LBA Lᵣ), then the data sector being requested is directly obtained at S31 and the data is sent back to the host. If s>1, lossless decompression is applied at S32 to the data in order to reconstruct the original data (denoted as D₀) consisting of the base sector and all the deltas. At S33, based upon the metadata block, the base sector and the delta associated with Lᵣ is used to reconstruct the data sector being requested and the data is sent back to the host 20.

It is also understood that the controller 10 may be implemented in any manner, e.g., as an integrated circuit board or a controller card that includes a processing core, I/O, processing logic and/or a software program. Aspects may be implemented in hardware or software, or a combination thereof. For example, aspects of the processing logic may be implemented using field programmable gate arrays (FPGAs), ASIC devices, or other hardware-oriented system.

Aspects may be implemented with a computer program product stored on a computer readable storage medium. The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, etc. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Java, Python, Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by hardware and/or computer readable program instructions.

The flowchart and block diagrams in the figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to an individual in the art are included within the scope of the invention as defined by the accompanying claims.

What is claimed is:

1. A solid-state storage device, comprising:
a set of flash memory;
a nonvolatile memory (NVM) cache; and
a controller that performs similarity-based data deduplication in response to write requests from a host, wherein the controller includes:
a cache management module that temporarily stores a new data sector in NVM cache after a write request is received;
a similarity detection module that determines if a similar data sector exists in flash memory;
a data chunk management module that, in response to determining the similar data sector exists, generates a new data chunk that includes a metadata block, a base sector and at least one delta, wherein the new data chunk is stored in a newly allocated physical block address (PBA) in flash memory.

2. The device of claim 1, wherein the metadata block includes a logical block address (LBA) of the base sector and an LBA and size of each delta.

3. The device of claim 1, wherein the at least one delta is generated with a delta compression engine.

4. The device of claim 3, wherein the base sector is compressed with a lossless compression engine.

5. The device of claim 1, wherein the data chunk management module determines if the similar sector is stored in an existing data chunk with at least one delta.

6. The device of claim 5, wherein if the existing data chunk does not include at least one delta, the data chunk management module generates the new data chunk in which the new data sector forms the base sector and the similar data sector is used to obtain the delta.

7. The device of claim 6, wherein if the existing data chunk includes at least one delta, the data chunk management module applies lossless decompression on the existing data chunk.

8. A solid-state storage device, comprising:
a set of flash memory;
a nonvolatile memory cache; and
a controller that performs similarity-based data deduplication, wherein the controller includes logic to perform the following when requested to write a new sector of data:
initially writing the new sector into nonvolatile memory;
determining if the new sector has a similar sector in the set of flash memory;
in response to determining that no similar sector exists, allocating a new physical block address (PBA) and storing the new sector to flash memory;
in response to determining that the similar sector exists, determining if the similar sector is part of a data chunk that includes deltas;
in response to determining that the similar sector is not part of an existing data chunk that includes deltas, creating a new data chunk that includes a base sector and a delta, and storing the new data chunk in flash memory;
in response to determining that the similar sector is part of the existing data chunk that includes deltas, determining whether a base sector of the existing data chunk still maps to a physical block address (PBA) of the existing data chunk; and
in response to determining that the base sector of the existing data chunk still maps to the physical block address, obtaining a delta for the new sector, appending the delta to the existing data chunk, and storing an updated data chunk into flash memory.

9. The device of claim 8, wherein the updated data chunk is stored to a new PBA.

10. The device of claim 8, wherein the new data chunk is stored to a new PBA.

11. The device of claim 8, wherein both the new data chunk and updated data chunk include a metadata block that includes a logical block address (LBA) of the base sector and an LBA and size of each delta.

12. The device of claim 8, wherein, in response to determining that the base sector of the existing data chunk does not map to the physical block address, reconstructing and original set of data from the existing data chunk, and selecting an alternate base sector.

13. The device of claim 12, further comprising generating new deltas using the alternate base sector.

14. The device of claim 8, wherein in response to receiving a read request for a requested data sector, the controller:
analyzes an LBA-PBA mapping table to obtain a PBA, and reads a corresponding data chunk;
analyzes a metablock from the corresponding data chunk;
if the corresponding data chunk does not include at least one delta, directly obtaining the requested data sector; and
if the corresponding data chunk includes at least one delta, applying lossless compression to reconstruct the base sector and deltas, and reconstructing the requested data sector.

15. A method for performing similarity-based data deduplication within a storage device having flash memory and a nonvolatile memory (NVM) cache, comprising:
temporarily storing a new sector in NVM cache on the data storage device after a write request is received;
determining if a similar sector exists in flash memory;
in response to determining the similar sector exists, generating a new data chunk that includes a metadata block, a base sector and at least one delta; and
storing the new data chunk in a newly allocated physical block address (PBA) in flash memory.

16. The method of claim 15, further comprising:
in response to determining that no similar sector exists, allocating a new physical block address (PBA) and storing the new sector to flash memory.

17. The method of claim 16, further comprising:
in response to determining that the similar sector exists, determining if the similar sector is part of a data chunk that includes deltas;
in response to determining that the similar sector is not part of an existing data chunk that includes deltas, creating a new data chunk that includes a base sector and a delta, and storing the new data chunk in flash memory;
in response to determining that the similar sector is part of the existing data chunk that includes deltas, determining whether a base sector of the existing data chunk still maps to a PBA of the existing data chunk; and
in response to determining that the base sector of the existing data chunk still maps to the physical block address, obtaining a delta for the new sector, appending the delta to the existing data chunk, and storing an updated data chunk into flash memory.

18. The method of claim 15, wherein both the new data chunk and updated data chunk include a metadata block that includes a logical block address (LBA) of the base sector and an LBA and size of each delta.

19. The method of claim 15, wherein, in response to determining that the base sector of the existing data chunk does not map to the physical block address, reconstructing and original set of data from the existing data chunk, and selecting an alternate base sector.

20. The method of claim 19, further comprising generating new deltas using the alternate base sector.
